(19) United States
(12) Patent Application Publication
(10) Pub. No.: US 2007/0063781 A1
(43) Pub. Date: Mar. 22, 2007

(54) Voltage controlled oscillator with amplitude control

(75) Inventor: Phoung T. Huynh, Annandale, VA (US)

Correspondence Address: POSZ LAW GROUP, PLC, 12040 SOUTH LAKES DRIVE, SUITE 101, RESTON, VA, 20191, US

(73) Assignee: FREESCALE SEMICONDUCTOR, INC.

(21) Appl. No.: 11/229,596

(22) Filed: Sep. 20, 2005

(51) Int. Cl. H03L 5/00

(52) U.S. Cl. 331/182

(57) ABSTRACT

A voltage controlled oscillator device with amplitude control is provided. A voltage controlled oscillator (VCO) (101) receives an input current. An error amplifier (117) compares an amplitude of oscillation (113) of the input current to a reference voltage (115) to provide a difference, and outputs a shunting current responsive to the difference. A feedback control reduces the input current to the VCO (101) responsive to the shunting current

### FIELD OF THE INVENTION

The present invention relates in general to a communication device utilizing a voltage controlled oscillator, and more specifically to voltage controlled oscillators having amplitude control.

### BACKGROUND OF THE INVENTION

A voltage control oscillator (VCO) is a well known component, and is typically utilized in communication devices. A VCO is used widely in many applications, especially in connection with a phase locked loop (PLL). In a PLL, the VCO provides a reference frequency utilized to multiply up to a desired, higher range.

Prior-art VCOs have utilized high supply voltage resulting in high power consumption. Some newer electronic devices, such as portable communication devices, utilize low voltage to conserve power. However, at a low voltage, the amplitude produced by the VCO can exceed a range limit, causing transistors in the VCO to saturate and degrade the VCO phase noise.

### BRIEF DESCRIPTION OF THE DRAWINGS

The accompanying figures where like reference numerals refer to identical or functionally similar elements and which together with the detailed description below are incorporated in and form part of the specification, serve to further illustrate an exemplary embodiment and to explain various principles and advantages in accordance with the present invention.

FIG. 1 is a schematic diagram illustrating an exemplary voltage controlled oscillator (VCO) with amplitude control, in accordance with one or more embodiments;

FIG. 2 is a schematic diagram illustrating an exemplary feedback control, in accordance with one or more embodiments;

FIG. 3 is a schematic diagram illustrating an exemplary peak detector in accordance with various first exemplary embodiments;

FIG. 4 is a schematic diagram illustrating an exemplary bottom detector in accordance with various first exemplary embodiments;

FIG. 5 is a schematic diagram illustrating an exemplary peak detector in accordance with various second exemplary embodiments;

FIG. 6 is a schematic diagram illustrating an exemplary bottom detector in accordance with various second exemplary embodiments;

FIG. 7 is a schematic diagram illustrating an exemplary error amplifier with peak and bottom detectors, in accordance with one or more embodiments;

FIG. 8 is a schematic diagram illustrating a topology of an exemplary YCO, in accordance with one or more embodiments;

FIG. 9 is a schematic diagram illustrating a topology of an exemplary bias generator, in accordance with one or more embodiments;

FIG. 10 is another schematic diagram illustrating an exemplary VCO with feedback control, in accordance with one or more embodiments;

FIG. 11 is a functional block diagram illustrating portions of an exemplary communication unit arranged for transmitting data utilizing a VCO with amplitude control, in accordance with various exemplary embodiments; and

FIG. 12 is a flow chart illustrating an exemplary procedure for providing amplitude control for a VCO, in accordance with various exemplary and alternative exemplary embodiments.

### DETAILED DESCRIPTION

In overview, the present disclosure concerns electronic devices or units, some of which are referred to as communication units, such as cellular phone or two-way radios and the like, typically having a capability for rapidly handling data, such as can be associated with a communication system such as an Enterprise Network, a cellular Radio Access Network, or the like. More particularly, various inventive concepts and principles are embodied in circuits, and methods therein for transmitting and/or receiving signals in connection with a communication unit.

The instant disclosure is provided to further explain in an enabling fashion the best modes of performing one or more embodiments of the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It is further understood that the use of relational terms such as first and second, and the like, if any, are used solely to distinguish one from another entity, item, or action without necessarily requiring or implying any actual such relationship or order between such entities, items or actions. It is noted that some embodiments may include a plurality of processes or steps, which can be performed in any order, unless expressly and necessarily limited to a particular order; i.e., processes or steps that are not so limited may be performed in any order.

Much of the inventive functionality and many of the inventive principles when implemented, are best supported with or in software or integrated circuits (ICs), such as a digital signal processor and software therefore or application specific ICs. It is expected that one of ordinary skill, notwithstanding possibly significant effort and many design choices motivated by, for example, available time, current technology, and economic considerations, when guided by the concepts and principles disclosed herein will be readily capable of generating such software instructions or ICs with minimal experimentation. Therefore, in the interest of brevity and minimization of any risk of obscuring the principles and concepts according to the present invention, further discussion of such software and ICs, if any, will be limited to the essentials with respect to the principles and concepts used by the exemplary embodiments.

As further discussed herein below, various inventive principles and combinations thereof are advantageously employed to provide a voltage controlled oscillator (VCO) capable of operating at a low voltage, that provide amplitude control.

Further in accordance with exemplary embodiments, there is provide a VCO with amplitude control. One or more embodiments provide that the VCO with amplitude control can be implemented in a bipolar topology. The VCO with amplitude control according to various embodiments can reduce the component count, which can lower VCO phase noise problems. The VCO can include a simple error amplifier with peak and/or bottom voltage sensors, and a shunting feedback mechanism. The VCO with amplitude control can be utilized in a device with a low voltage, such as at 3.3V or below.

In overview, one or more embodiments provide a voltage controlled oscillator device with amplitude control. There is included a voltage controlled oscillator (VCO) receiving an input current. An error amplifier compares an amplitude of oscillation of the input current to a reference voltage, for example, a V_{BE}, to provide a difference. The error amplifier outputs a shunting current responsive to the difference. A feedback control reduces the input current to the VCO responsive to the shunting current.

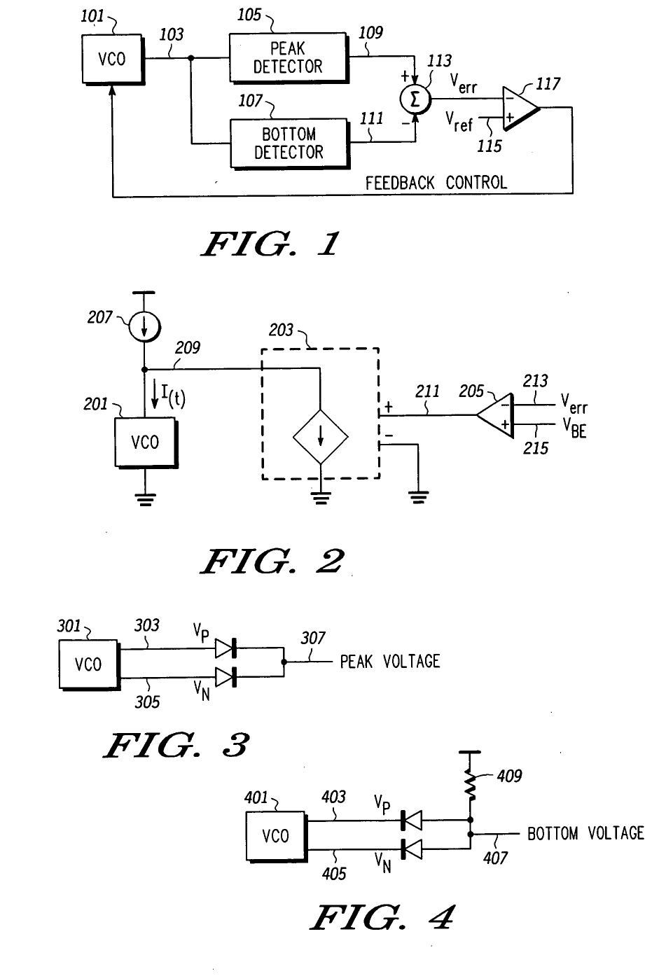

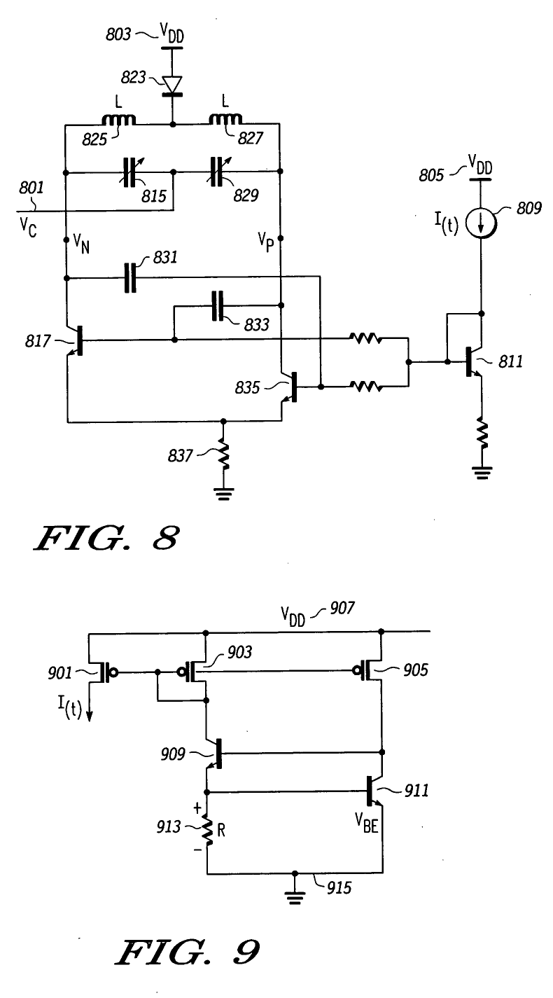

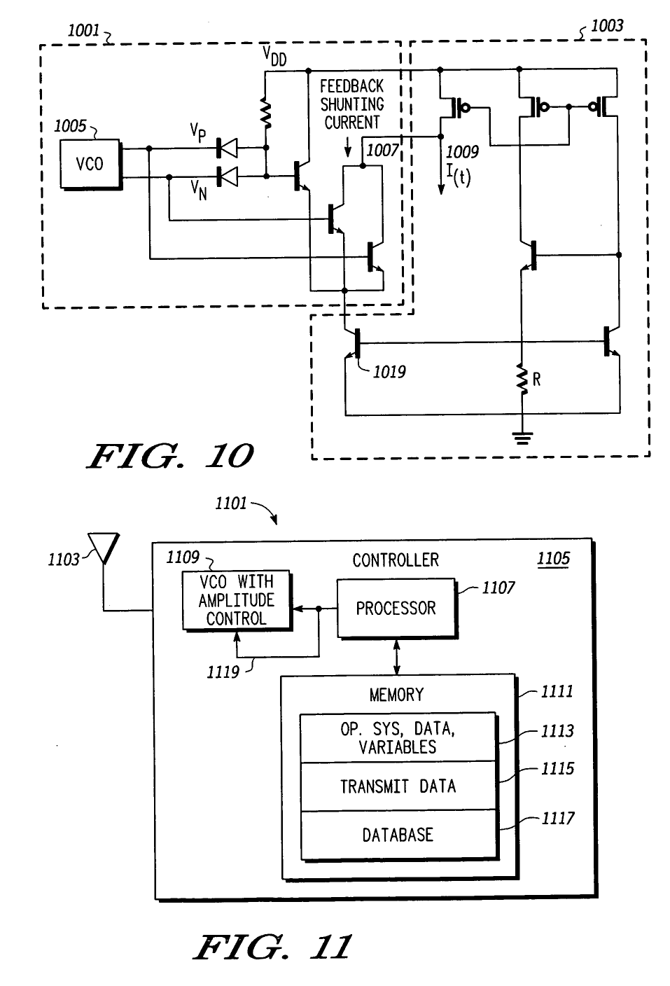

In overview, an overall schematic diagram of a VCO with amplitude control is illustrated in FIG. 1. FIG. 2 and FIG. 7-9 illustrate components which can be used in one or more embodiments of a VCO with amplitude control. FIG. 2 illustrates an exemplary feedback control. FIG. 7 illustrates an exemplary error amplifier with peak and bottom detectors, such as illustrated in FIG. 3-FIG. 6. FIG. 8 illustrates an exemplary VCO. FIG. 9 illustrates a topology of an exemplary bias generator. FIG. 10 provides another overall schematic diagram illustrating an exemplary VCO with feedback control.

Referring now to FIG. 1, a schematic diagram illustrating an exemplary voltage controlled oscillator (VCO) with amplitude control, in accordance with one or more embodiments, will be discussed and described. In overview, the VCO provides control for the amplitude of oscillation. A VCO 101 outputs a signal 103 which is in the form of a sine wave, with a peak voltage and a bottom voltage. An amplitude control can seek to maintain the difference between the peak voltage and the bottom voltage.

To maintain the difference, a peak voltage detector 105 and a bottom voltage detector 107 can sense the peak and the bottom voltages Vₚₑₐₖ and V_{bottom}, respectively, and provide a signal representing the peak voltage 109 and a signal representing the bottom voltage 111.

A difference 113 between the peak and bottom voltages 109, 111 can be obtained, to provide the error voltage Vₑᵣᵣ. The error voltage Vₑᵣᵣ can be compared to a reference voltage 155 V_{ref}, to provide a difference. The error voltage represents the difference between the peak voltage and the bottom voltage, that is Vₑᵣᵣ=Vₚₑₐₖ−V_{bottom}. The amplifier can generate a signal representing the difference 117, which can be fed back to the VCO 101 to keep the error voltage Vₑᵣᵣ constant and equal to the reference voltage.

Referring now to FIG. 2, a schematic diagram illustrating an exemplary feedback control in accordance with one or more embodiments will be discussed and described. In the illustrated embodiment, a VCO 201 is sourced by a current source I(t) 207. If the current source 207 increases its magnitude, the amplitude of a signal produced by the VCO 201 increases. Similarly, if the current source 207 decreases its voltage, the amplitude of the signal produced by the VCO 201 decreases.

Changes in amplitude of the signal produced by the VCO 201 can be controlled by selectively shunting, that is, reducing the magnitude of current source 207 to the VCO 201. A shunting current 209 can be provided by utilizing an error voltage 213 Vₑᵣᵣ and a reference voltage, as will be described in greater detail below. The reference voltage in the illustrated embodiment is V_{BE} 215 (base to emitter).

The reference voltage V_{BE} 215 can provide a virtually constant voltage (being virtually constant since it can vary with environmental conditions such as with temperature). The reference voltage V_{BE} 215 can be provided by, for example, an NPN transistor in accordance with known techniques.

The amplitude of a signal output by the VCO can be controlled in correspondence to the difference 205 between the error voltage Vₑᵣᵣ 213 and the reference voltage V_{BE} 215, the difference being provided as a control voltage 211. The control voltage 211 can be used to control a feedback shunting current 209, which selectively decreases and/or increases the current source I(t) 207 to the VCO. Because the current to the VCO is controlled, the amplitude of the signal from the VCO can be controlled and kept equal to the reference voltage V_{BE}.

Where the amplitude of oscillation of the output signal is determined to be too large, a shunting to ground 203 from the current source can be increased, to reduce the current source to the VCO, thereby providing a negative feedback. Similarly, where the amplitude of oscillation is determined to be too small, the shunting to ground 203 from the current source can be decreased, to increase the current source to the VCO.

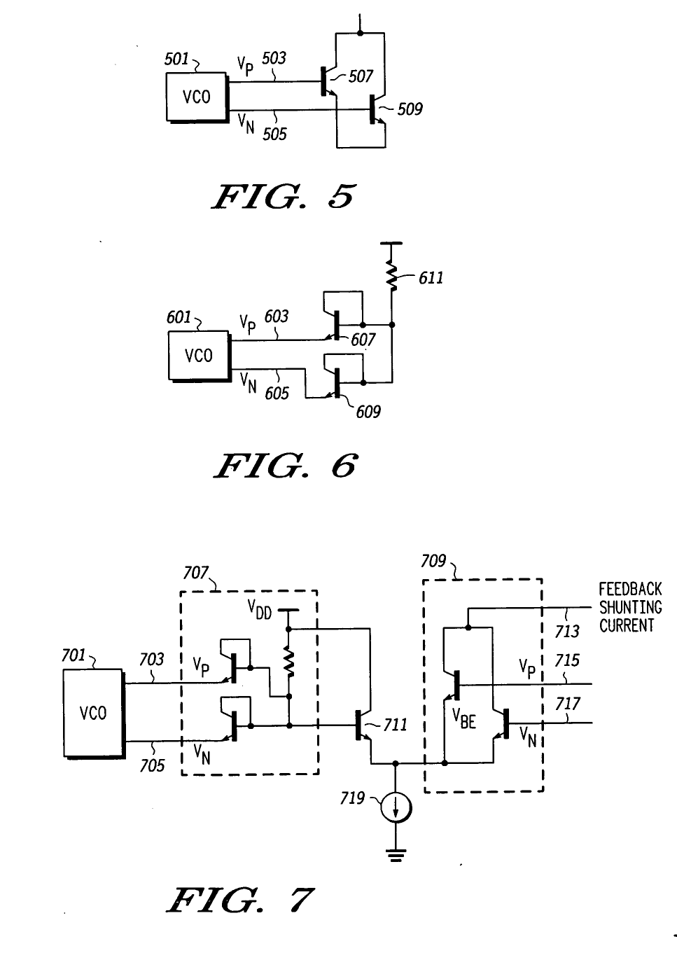

FIG. 3-FIG. 6 illustrate various embodiments for sensing peak voltage and bottom voltage. FIG. 3 and FIG. 4 illustrate a first embodiment of a peak detector and a bottom detector, respectively, utilizing diodes. FIG. 5 and FIG. 6 illustrate a second embodiment of a peak detector and a bottom detector, respectively, utilizing NPN transistors.

Referring now to FIG. 3, a schematic diagram illustrating an exemplary peak detector in accordance with various first exemplary embodiments will be discussed and described. The output signal from the VCO 301, V_{P} (positive terminal of VCO output) 303 and V_{N} (negative terminal of VCO output) 305 are received by respective first and second diodes, which are tied together, to provide a signal 307 representing the peak voltage which has been detected.

Referring now to FIG. 4, a schematic diagram illustrating an exemplary bottom detector in accordance with various first exemplary embodiments will be discussed and described. The output of terminals of the VCO 401, V_{P} 403 and V_{N} 405 are received by respective first and second diodes, which are tied together. Note that the polarities of the first and second diodes are reversed with respect to those illustrated in FIG. 4. This provides a signal 407 representing the bottom voltage which has been detected. A resistor 409 is combined with the bottom voltage 407 to provide a current path.

Referring now to FIG. 5, a schematic diagram illustrating an exemplary peak detector in accordance with various second exemplary embodiments will be discussed and described. The output of terminals of the VCO 501, V_{P} 503 and V_{N} 505 are received by respective first and second NPN transistors 507, 509, which are tied together, to provide a signal representing the peak voltage.

Referring now to FIG. 6, a schematic diagram illustrating an exemplary bottom detector in accordance with various second exemplary embodiments will be discussed and described. The outputs of terminals of the VCO 601, V_{P} 603 and V_{N} 605 are received by respective first and second NPN transistors 607, 609, which are tied together, to provide a signal representing the bottom voltage. A resistor 611 is combined with the bottom voltage to provide a current path.

Referring now to FIG. 7, a schematic diagram illustrating an exemplary error amplifier with peak and bottom detectors in accordance with one or more embodiments will be discussed and described. The differential signal 703, 705, 715, 717 from a VCO 701 is fed to a peak voltage detector 709 and a bottom voltage detector 707, such as those described in connection with FIG. 3-FIG. 6. Also provided are a combining NPN transistor 711 and a constant current with ground 719 to form the error amplifier.

One or more embodiments therefore can sense the peak voltage and the bottom voltage, to provide an error amplifier that inputs the difference between the peak and bottom voltages, and can compare the difference to a base-to-emitter voltage V_{BE}, such as is provided in the peak voltage detector 709. A feedback shunting current 713 can then be provided which represents the difference of the peak voltage and the bottom voltage, compared to the base-to-emitter voltage V_{BE}. The feedback shunting current can be utilized to shunt an appropriate amount of current from the signal input to the VCO.

Accordingly, one or more embodiments comprise a peak detector and a bottom detector, receiving an output from the VCO and providing the amplitude of oscillation to the error amplifier. At least one of the peak detector and the bottom detector is differential. Both the peak detector and the bottom detector can be differential.

Referring now to FIG. 8, a schematic diagram illustrating a topology of an exemplary VCO in accordance with one or more embodiments will be discussed and described. The illustrated embodiment provides a topology of a low voltage, bi-polar VCO with a current source I(t) 809. A controlled voltage VC 801 is provided in accordance with known techniques to control the frequency of the VCO.

The illustrated topology includes first NPN transistor 817 and second NPN transistor 835, each being cross-coupled to the other. The first and second NPN transistors 817, 835 can be tied to V_{P} and V_{N}. In this embodiment, the base of each NPN transistor 817, 835 is connected via capacitors 831, 833 to each other. Accordingly, one or more embodiments provide that the VCO comprises two transistors cross coupled to each other. More particularly, one or more embodiments provide that the VCO comprises two bipolar transistors cross coupled to each other. Further, one or more embodiments provide that the VCO is bipolar.

The VC 801 is tied to first and second varactors 815, 829, which are tied to V_{P} and V_{N}. The V_{DD} 803 provided through a diode 823 and through first and second inductors L 825, 827. The diode 823 is optional.

A supply voltage V_{DD} 805 can provide the current source I(t) 809. The current source 809 can control the amplitude of the signal Vₚ, Vₙ produced by the VCO. If the current source 809 is increased, the amplitude of oscillation of the signal produced by the VCO will increase. Similarly, if the current source 809 is reduced, the amplitude of oscillation of the signal produced by the VCO will decrease. The current source I(t) 809 can be tied through third NPN transistor 811 to the first and second NPN transistors 817, 835. Accordingly, one or more embodiments can provide a cross coupled, bi-polar VCO, which is particularly useful in low voltage applications, e.g., those at 3.3V and below, more particularly at 2.5V or lower, and more particularly at 1.8V.

One or more embodiments provide that current source can be generated via a bias generator. Referring now to FIG. 9, a schematic diagram illustrating a topology of an exemplary bias generator in accordance with one or more embodiments will be discussed and described.

The illustrated embodiment is a self-biasing generator. Accordingly, one or more embodiments comprise a self-biasing generator, providing a bias current to the VCO.

In the illustrated embodiment, first, second and third p-channel MOSFETs 901, 903, 905 all receive a supply voltage V_{DD} 907. The first, second and third p-channel MOSFETs 901, 903, 905 are tied together.

Resistor R 913 is tied to a first NPN transistor 909 and a second NPN transistor 911 providing V_{BE}. The current of the resistor 913 is V_{BE}/R. Therefore, I=V_{BE}/R, where I is the current source.

Also, a ground 915 is provided. The output of the current generator is the current source I(t). The current source I(t) from the bias generator is supplied as the current source I(t) of the VCO, shown for example in FIG. 8.

Referring now to FIG. 10, another schematic diagram illustrating an exemplary VCO with feedback control in accordance with one or more embodiments will be discussed and described. FIG. 10 illustrates an overall combination of components illustrated and discussed previously in connection with FIG. 2 (an exemplary feedback control), FIG. 7 (an exemplary error amplifier) and FIG. 9 (an exemplary bias generator). Each of these has been previously described in detail, which will not be repeated here.

An error amplifier 1001 and a bias generator 1003 are tied together with an tying NPN transistor 1019. A feedback shunting current 1007, in accordance with previously described embodiments, can remove some of the current source I(t) 1009 which will be provided to the VCO 1005, thereby provide amplitude control to the VCO 1005.

Accordingly, one or more embodiments can provide a voltage controlled oscillator circuit having an amplitude control. There is included a bipolar voltage controlled oscillator (VCO) receiving an input current having a voltage lower than 3.3V. Also provided is an error amplifier comparing an amplitude of oscillation of the VCO to a reference voltage to provide a difference, and outputting a shunting current responsive to the difference. Also provided is a feedback control reducing the input current to the VCO responsive to the shunting current.

Referring now to FIG. 11, a functional block diagram illustrating portions of an exemplary communication unit 1101 arranged for transmitting data utilizing a VCO with amplitude control, in accordance with various exemplary embodiments will be discussed and described. The communication unit 1101 may include a transceiver 1103 and one or more controllers 1105. A controller 1105 may include a processor 1107, a memory 1111, and VCO 1109 in-line with the processor 1107 and transceiver 1103. The VCO can include amplitude control 1119. Many other components that can be included are well understood to those of skill, and are not discussed herein in order for the sake of simplicity. The transceiver 1103 could be replaced by a transmitter and/or a receiver.

The communication unit 1101 may be referred to as a low voltage unit, providing voltage lower than is conventional to the VCO 1109. Typically, a low voltage unit supplies input current to the VCO of 3.3V or less. Generally, the input current is between 3.3V and 1.8V. More precisely, the input current can be 2.5V. However, the voltage of the input current provided by the communication unit to the VCO 1109 can be lower than 1.8V.

The processor 1107 may comprise one or more microprocessors and/or one or more digital signal processors. The memory 1111 may be coupled to the processor 1107 and may comprise a read-only memory (ROM), a random-access memory (RAM), a programmable ROM (PROM), and/or an electrically erasable read-only memory (EEPROM). The memory 1111 may include multiple memory locations for storing, among other things, an operating system, data and variables 1113 for programs executed by the processor 1107; computer programs for causing the processor to operate in connection with various functions such as transmitting data 1115 and/or receiving data (not illustrated), and/or other processing (not illustrated); and a database 1117 of information used by the processor 1117. The computer programs may be stored, for example, in ROM or PROM and may direct the processor 1107 in controlling the operation of the communication unit 1101.

The processor 1107 may be programmed for transmitting data 1115, where the data represents information that is to be transmitted, i.e. transmit data. The transmit data can be provided in accordance with well-known components, e.g., as output from an A/D converter, as input digital information, as output from a base band chip, or the like. Similarly, the processor 1107 can be programmed for receiving data (not illustrated). The data is transmitted or received in connection with components that utilize the VCO 1109, for example to provide an accurate reference frequency. The amplitude control 1119 can enhance the accuracy of the VCO accuracy, which can be particularly useful in application such as those utilizing a high data rate.

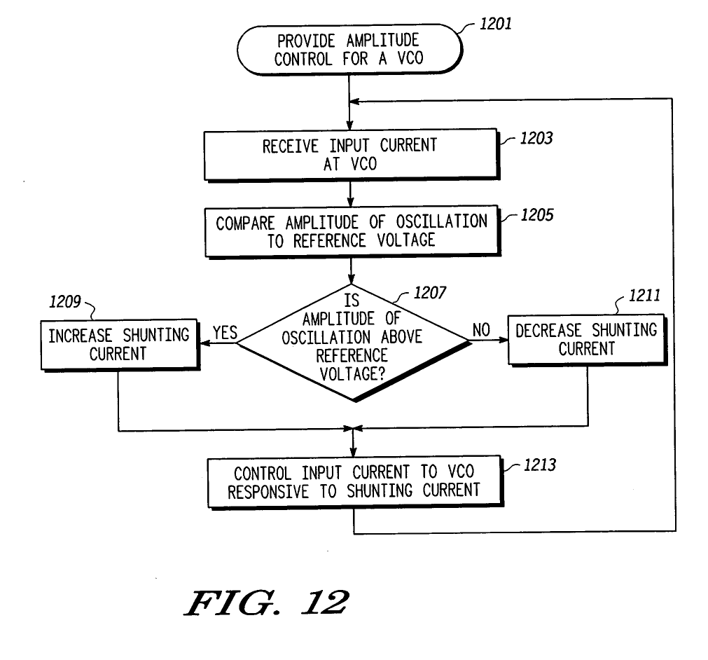

Referring now to FIG. 12, a flow chart illustrating an exemplary procedure for providing amplitude control for a VCO 1201, in accordance with various exemplary and alternative exemplary embodiments will be discussed and described. The procedure can advantageously be implemented in, for example, a VCO with amplitude control described in connection with FIG. 1 or other apparatus appropriately arranged.

In overview, the procedure for providing amplitude control for a VCO 1201 includes receiving 1203 an input current at a VCO; comparing 1205 the amplitude of oscillation to a reference voltage; and determining 1207 whether the amplitude of oscillation is above the reference voltage. If the amplitude of oscillation is above the reference voltage, then the shunting current is increased 1209. If the amplitude of oscillation is not above the reference voltage, then the shunting current is decreased 1211. The procedure includes controlling 1213 the input current to the VCO responsive to the shunting current. The procedure can be repeated continuously. The portions of the procedure are now described in more detail.

An input current can be received 1203 at a VCO. The input current is provided by the device in which the VCO is used, and hence is determined by the communication unit generating the input current. The input current typically can operate between 3.3V and 1.8V. Thus, the supply voltage to the VCO can be provided at a voltage of less than 3.3V. More particularly, the input current can be 2.5V. Even more particularly, the input current can be provided at a voltage of between 2.5V and 1.8V. Even more particularly, the voltage of the input current can be lower than 1.8V. Accordingly, one or more embodiments provide for a circuit or a method in a communication unit generating the input current having the voltage.

Based on the input current, the VCO can provide an output signal, in accordance with known techniques, which is in the form of a sine wave. The output signal can exhibit an amplitude of oscillation, that is, the amplitude between the peak and bottom of the sine wave. Note that the amplitude of oscillation can vary when the VCO is in operation, for example due to temperature changes.

The amplitude of oscillation of the signal from the VCO can be compared 1205 to a reference voltage. The amplitude of oscillation can be determined by observing the peak voltage and the bottom voltage of the signal. Accordingly, one or more embodiments provide for detecting a peak voltage in the input current; and/or detecting a bottom voltage in the input current. The peak voltage and bottom voltage can be utilized to determine their difference. The difference is referred to as the amplitude of oscillation. Accordingly, one or more embodiments provide for detecting a peak voltage in a VCO output and detecting a bottom voltage in the VCO output, and providing a difference between the peak and the bottom as the amplitude of oscillation.

Also, one or more embodiments provide that the detecting is performed by a bipolar component. Alternatively, the detecting can be performed in a CMOS component.

In accordance with one or more embodiments, the VCO is bipolar. For example, the VCO can comprise at least two bipolar transistors cross coupled to each other. Alternatively, the VCO can comprise CMOS topology.

The procedure also provides for determining 1207 whether the amplitude of oscillation is above the reference voltage. The amplitude of oscillation can be produced by determining the difference between the peak voltage and the bottom voltage. The amplitude of oscillation can be compared to a reference voltage. The reference voltage can be provided in accordance with known techniques. If the amplitude of oscillation is equal to the reference voltage, then there is no need for adjustment. If the amplitude of oscillation is not equal to the reference voltage, then the input current can be adjusted.

If the amplitude of oscillation is above the reference voltage, then the shunting current is increased 1209. On the other hand, if the amplitude of oscillation is below the reference voltage, then the shunting current is decreased 1211. Accordingly, one or more embodiments provides for comparing an amplitude of oscillation of the input current to a reference voltage, and outputting a shunting current responsive to the comparing. Further, one or more embodiments provides for increasing the shunting current when the amplitude of oscillation exceeds the reference voltage, and decreasing the shunting current when the amplitude of oscillation is below the reference voltage.

Adjustment to the input current to the VCO can be made utilizing the shunting current, which shunts voltage away from the input current. The procedure therefore includes controlling 1213 the input current to the VCO responsive to the shunting current.

It should be noted that many components described herein can be implemented with CMOS instead of bipolar transistors.

It should be noted that the term communication unit may be used herein to denote a wired device, for example a high speed modem, an xDSL type modem, a wireline UWB device, and the like, and a wireless device, and typically a wireless device that may be used with a public network, for example in accordance with a service agreement, or within a private network such as an enterprise network or an ad hoc network. Examples of such communication devices include a cellular handset or device, television apparatus, personal digital assistants, personal assignment pads, and personal computers equipped for wireless operation, and the like, or equivalents thereof, provided such devices are arranged and constructed for operation in connection with wired or wireless communication.

The communication units of particular interest are those providing or facilitating voice communications services or data or messaging services normally referred to as ultra wideband networks, cellular wide area networks (WANs), such as conventional two way systems and devices, various cellular phone systems including analog and digital cellular, CDMA (code division multiple access) and variants thereof, GSM (Global System for Mobile Communications), GPRS (General Packet Radio System), 2.5G and 3G systems such as UMTS (Universal Mobile Telecommunication Service) systems, Internet Protocol (IP) Wireless Wide Area Networks like 802.16, 802.20 or Flarion, integrated digital enhanced networks and variants or evolutions thereof.

Furthermore, the wireless communication devices of interest may have short range wireless communications capability normally referred to as WLAN (wireless local area network) capabilities, such as IEEE 802.11, Bluetooth, WPAN (wireless personal area network) or Hiper-Lan and the like using, for example, CDMA, frequency hopping, OFDM (orthogonal frequency division multiplexing) or TDMA (Time Division Multiple Access) access technologies and one or more of various networking protocols, such as TCP/IP (Transmission Control Protocol/Internet Protocol), UDP/UP (Universal Datagram Protocol/Universal Protocol), IPX/SPX (Inter-Packet Exchange/Sequential Packet Exchange), Net BIOS (Network Basic Input Output System) or other protocol structures. Alternatively the wireless communication devices of interest may be connected to a LAN using protocols such as TCP/IP, UDP/UP, IPX/SPX, or Net BIOS via a hardwired interface such as a cable and/or a connector.

This disclosure is intended to explain how to fashion and use various embodiments in accordance with the invention rather than to limit the true, intended, and fair scope and spirit thereof. The invention is defined solely by the appended claims, as they may be amended during the pendency of this application for patent, and all equivalents thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A voltage controlled oscillator device with amplitude control, comprising:
a voltage controlled oscillator (VCO) receiving an input current;
an error amplifier comparing an amplitude of oscillation of the input current to a reference voltage to provide a difference, and outputting a shunting current responsive to the difference; and
a feedback control, reducing the input current to the VCO responsive to the shunting current.

2. The device of claim 1, wherein a supply voltage to the VCO is less than 3.3V.

3. The device of claim 1, wherein the VCO is bipolar.

4. The device of claim 1, wherein the VCO comprises two bipolar transistors cross coupled to each other.

5. The device of claim 1, wherein the shunting current is increased when the amplitude of oscillation exceeds the reference voltage.

6. The device of claim 1, further comprising a peak detector and a bottom detector, receiving an output from the VCO and providing the amplitude of oscillation to the error amplifier.

7. The device of claim 6, wherein at least one of the peak detector and the bottom detector is differential.

8. A method for providing amplitude control for a voltage controlled oscillator in a circuit, comprising:
receiving an input current at a voltage controlled oscillator (VCO);
comparing an amplitude of oscillation of the input current to a reference voltage, and outputting a shunting current responsive to the comparing;
controlling the input current to the VCO responsive to the shunting current.

9. The method of claim 8, further comprising detecting a peak voltage in the input current, wherein the detecting is bipolar.

10. The method of claim 8, further comprising detecting a bottom voltage in the input current, wherein the detecting is bipolar.

11. The method of claim 8, further comprising providing the input current at a voltage of less than 3.3V.

12. The method of claim 8, wherein the VCO is bipolar.

13. The method of claim 8, wherein the VCO comprises two bipolar transistors cross coupled to each other.

14. The method of claim 8, further comprising increasing the shunting current when the amplitude of oscillation exceeds the reference voltage, and decreasing the shunting current when the amplitude of oscillation is below the reference voltage.

15. The method of claim 14, further comprising detecting a peak voltage in a VCO output and detecting a bottom voltage in the VCO output, and providing a difference between the peak and the bottom as the amplitude of oscillation.

16. A voltage controlled oscillator circuit having an amplitude control, comprising:
a bipolar voltage controlled oscillator (VCO) receiving an input current having a voltage lower than 3.3V;
an error amplifier comparing an amplitude of oscillation of the VCO to a reference voltage to provide a difference, and outputting a shunting current responsive to the difference; and
a feedback control reducing the input current to the VCO responsive to the shunting current.

17. The circuit of claim 16, wherein the circuit is provided in a communication unit generating the input current having the voltage.

18. The method of claim 16, further comprising a self-biasing generator, providing a bias current to the VCO.

19. The method of claim 16, wherein the VCO comprises two transistors cross coupled to each other.

20. The method of claim 16, wherein the voltage of the input current is lower than 1.8V.
